(19) United States
(12) Patent Application Publication
(10) Pub. No.: US 2020/0388659 A1
(43) Pub. Date: Dec. 10, 2020

(54) DISPLAY DEVICES

(71) Applicant: Flexenable Limited, Cambridge (GB)

(72) Inventors: Charlotte Harrison, Cambridge (GB); Shane Norval, Cambridge (GB)

(21) Appl. No.: 16/764,521

(22) PCT Filed: Nov. 12, 2018
(86) PCT No.: PCT/EP2018/080912

§ 371 Date: May 15, 2020

(30) Foreign Application Priority Data
Nov. 17, 2017 (GB) 1719079.4

(51) Int. Cl. H01L 27/32; G02F 1/1362; G02F 1/1368

(52) U.S. Cl. CPC H01L 27/3248; G02F 1/136227; G02F 1/1368; H01L 2227/323; H01L 27/3258; G02F 2202/022; H01L 27/3274

(57) ABSTRACT

A technique comprising: providing a workpiece including a stack of layers defining an array of transistors including organic semiconductor channels, wherein the stack of layers comprises an upper conductor pattern (8) defining an array of upper conductor elements, each in contact with a respective lower conductor element (6) of a lower conductor pattern in via-hole regions (10); the method comprising: processing the workpiece by forming over the upper conductor pattern a plugging layer that raises the upper surface level of the workpiece in at least the via-hole regions whilst leaving at least a portion of each upper conductor element exposed; and providing an optical medium (36) over the upper conductor pattern without first forming an inorganic moisture barrier layer on the upper surface of the workpiece.

Some display devices include a backplane component comprising a stack of layers defining an array of transistors including organic semiconductor channels. A technique aimed at improving the aperture ratio involves forming pixel conductors at a different level to the source and drain conductors of the transistors, and forming via-holes in the stack by which the pixel conductors contact a lower conductor pattern defining the source and drain conductors of the transistors.

The display device may, for example, be a liquid crystal display (LCD) device or a light-emitting diode (LED) device.

In the case of a LCD device, the liquid crystal material typically occupies a space between the backplane component and another support component. In the case of a LED device, bank structures are formed over the conductor pattern defining the array of pixel conductors, and one or more LED materials (including an organic light-emitting material) are deposited into wells defined by the bank structures.

The inventors for the present application have conducted work into improving the display performance of display devices including the above-described kind of backplane component.

There is hereby provided a method comprising: providing a workpiece including a stack of layers defining an array of transistors including organic semiconductor channels, wherein the stack of layers comprises an upper conductor pattern defining an array of upper conductor elements, each in contact with a respective lower conductor element of a lower conductor pattern in via-hole regions; the method comprising: processing the workpiece by forming over the upper conductor pattern a plugging layer that raises the upper surface level of the workpiece in at least the via-hole regions whilst leaving at least a portion of each upper conductor element exposed; and providing an optical medium over the upper conductor pattern without first forming an inorganic moisture barrier layer on the upper surface of the workpiece.

According to one embodiment, the upper surface of the plugging layer is no lower than the upper surface of the upper conductor pattern outside the via-hole regions.

According to one embodiment, the optical medium comprises a liquid crystal material, and the method comprises forming an alignment layer on the upper surface of the workpiece over the upper conductor pattern without first forming an inorganic moisture barrier layer over the upper surface of the workpiece.

According to one embodiment, the optical medium comprises a light-emitting diode comprising an organic light-emitting material, and the method comprises forming an element of the light-emitting diode over the upper surface of the workpiece without first forming an inorganic moisture barrier layer over the upper surface of the workpiece.

According to one embodiment, forming the plugging layer comprises forming a planarization layer over the upper surface of the work piece, and then patterning the planarization layer to expose at least a portion of each of the upper conductive elements.

According to one embodiment, the method further comprises forming a further conductor pattern over the planarization layer, the further conductor pattern defining an array of further conductive elements each in contact with a respective one of the upper conductive elements, wherein the area occupied by each further conductive element includes the via-hole region in which the respective upper conductive element contacts the respective lower conductive element.

There is also hereby provided a display device, comprising: a stack of layers defining an array of transistors including organic semiconductor channels, wherein the stack of layers comprises an upper conductor pattern defining an array of upper conductor elements, each in contact with a respective lower conductive element of a lower conductor pattern in a respective via-hole region; a patterned planarization layer that extends at least to the upper surface of the upper conductor pattern in the via-hole regions, and leaves at least a portion of each upper conductive element exposed; and an optical medium over the upper conductor pattern without any inorganic moisture barrier layer between the upper conductor pattern and the optical medium.

According to one embodiment, the optical medium comprises a liquid crystal material, and device comprises an alignment layer over the upper conductor pattern without any inorganic moisture barrier layer between the upper conductor pattern and the alignment layer.

According to one embodiment, the optical medium comprises a light-emitting diode comprising an organic light-emitting material, and the display device comprises an element of the light-emitting diode over the upper conductor pattern without any inorganic moisture barrier layer between the upper conductor pattern and said element of the light-emitting diode.

According to one embodiment, the display device further comprises a further conductor pattern over the patterned planarization layer, the further conductor pattern defining an array of further conductive elements each in contact with a respective one of the upper conductive elements; wherein the area occupied by each further conductive element includes the via-hole region in which the respective upper conductive element contacts the respective lower conductive element.

Embodiments of the invention are described hereunder by way of example only, with reference to the accompanying drawings, in which:

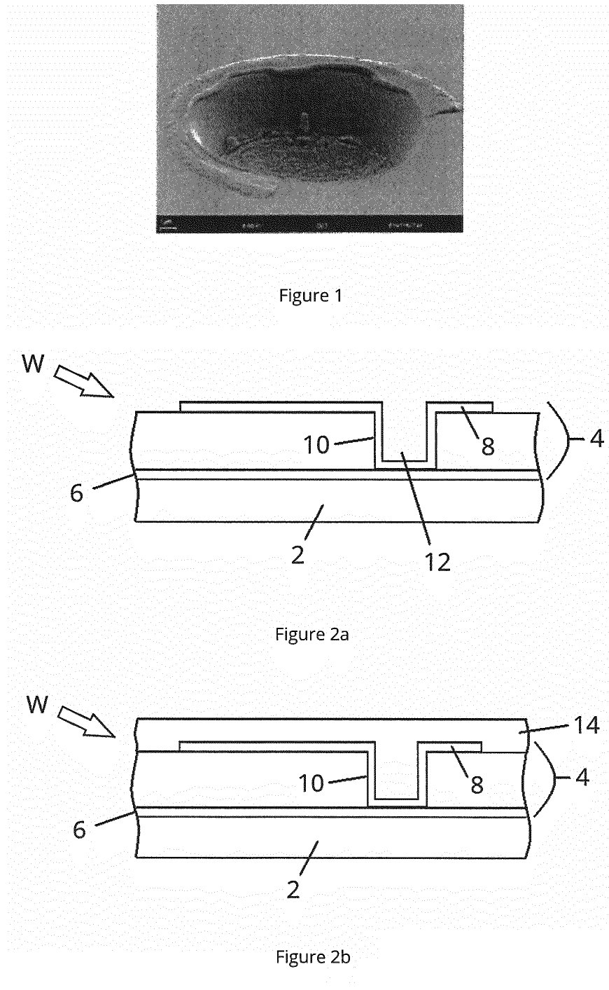

FIG. 1 illustrates a depression after deposition of a conductor over a workpiece including via-holes.

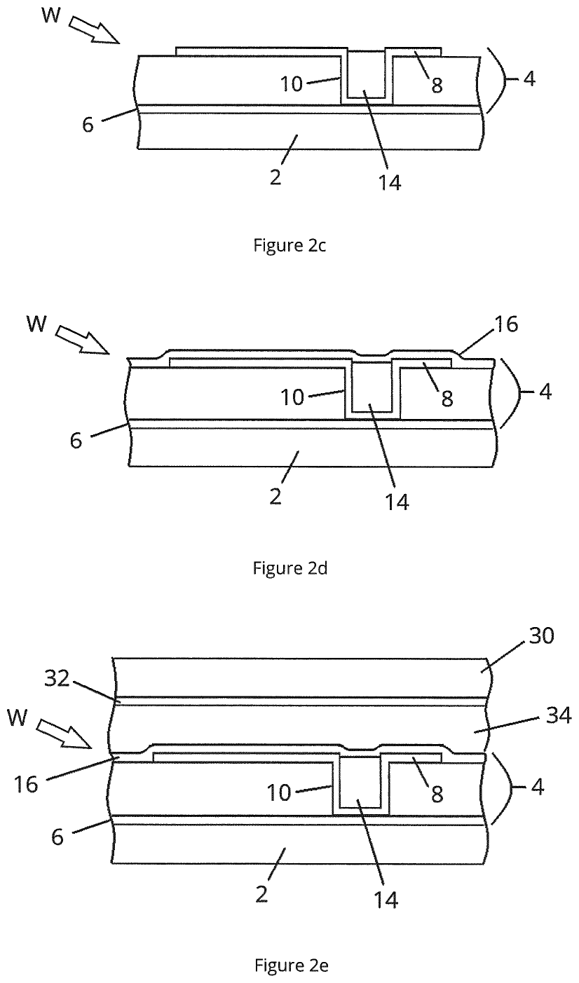

FIGS. 2(a) to 2(e) illustrate a method according to a first example embodiment of the present invention; and

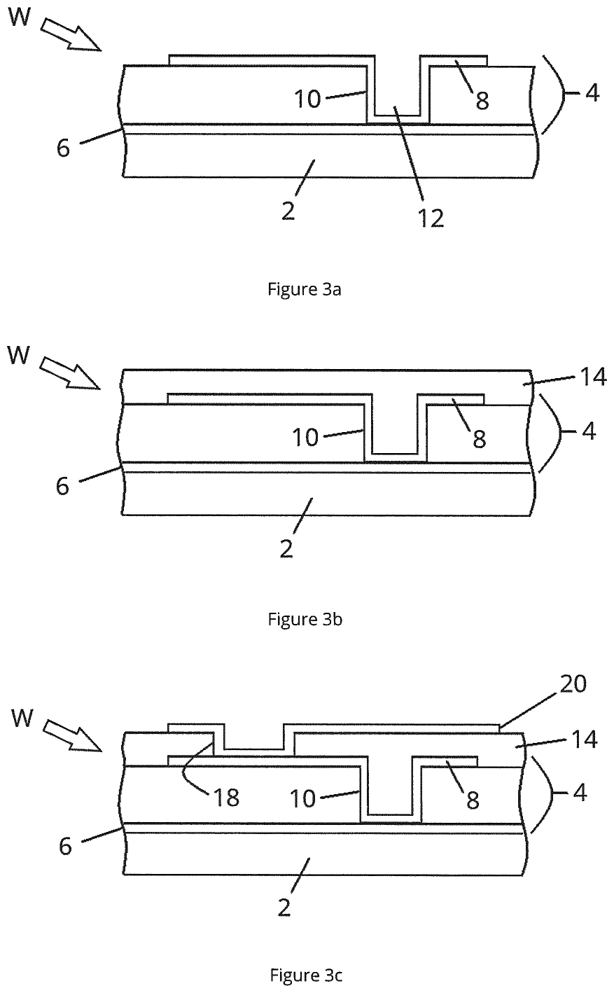

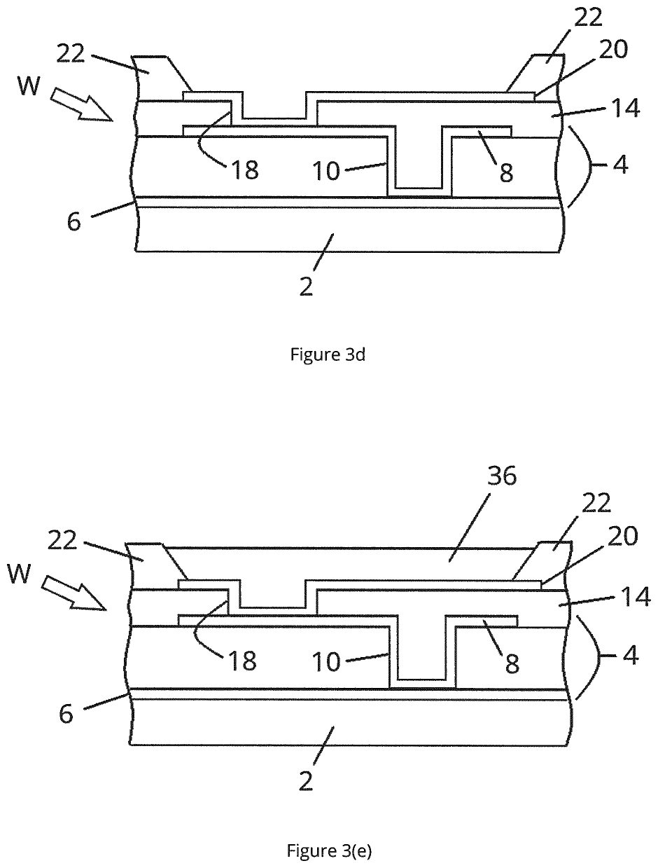

FIGS. 3(a) to 3(e) illustrate a method according to a second example embodiment of the present invention.

In one example embodiment, the technique is used for the production of an organic liquid crystal display (OLCD) device, which comprises an organic transistor device (such as an organic thin film transistor (OTFT) device) for the control component. OTFTs comprise an organic semiconductor (such as e.g. an organic polymer or small-molecule semiconductor) for the semiconductor channels

FIGS. 2(a) to 2(e) and 3(a) to 3(e) show the processing of a workpiece W from the stage that it comprises a stack 4 of conductor, semiconductor and insulator layers supported on a support component 2, such as e.g. a plastic support film. The stack of layers 4 define an array of transistors, each comprising an organic semiconductor channel provided by a patterned or unpatterned layer of organic semiconductor channel material, such as an organic polymer semiconductor.

The stack of layers 4 includes conductor patterns at a plurality of levels. One of the conductor patterns 6 defines the source and drain conductors for the array of transistors. For example, this conductor pattern 6 may define (i) an array of source conductors each providing the source electrodes for a respective row of transistors and extending to an edge of the array for connection to a respective terminal of a driver chip, and (ii) an array of drain conductors, each providing the drain electrode for a respective transistor.

The term “source conductor” is used here to define a conductor between the driver chip and the semiconductor channel of a transistor and the term “drain conductor” is used here to define a conductor connected to the driver chip via the semiconductor channel of the transistor.

The terms “row” and “column” do not indicate particular absolute directions, but together indicate a pair of substantially orthogonal directions.

Another conductor pattern 8 at a higher level of the stack defines an array of pixel conductors each in contact with a respective drain conductor of the lower conductor pattern 6 in via-hole regions, in which holes 10 have been opened in the stack by a patterning technique such as e.g. photolithography or laser ablation. The holes 10 may, for example, have a diameter of about 15 microns.

In this example of an array of top-gate transistors, another middle conductor pattern (not shown) defines an array of gate conductors, each providing the gate electrode for a respective column of transistors, such that each transistor in the array is associated with a unique combination of source and gate conductors. The stack of layers 4 may include additional conductor patterns at additional levels.

The upper conductor pattern 8 is formed by a conformal deposition method such as sputtering, according to which the topographic profile of the deposited conductor layer substantially matches the topographic profile of the work piece on to which the conductor is deposited. The thickness of the conductor layer 8 is substantially less than the diameter of the via-holes, such that the topographic profile of the workpiece after conductor deposition includes depressions 12 of the kind illustrated in the scattering electron microscopy (SEM) image of FIG. 1.

The deposited conductor layer is patterned, e.g. by etching via a photolithographically patterned photoresist mask or by laser ablation, to form conductor pattern 8 defining an array of pixel conductors each in contact with a respective drain conductor of the lower conductor pattern 6.

According to the example embodiment of FIGS. 2(a) to 2(e), the upper surface of the workpiece W is then processed by depositing over the workpiece, by a non-conformal deposition technique, a liquid which, after drying, leaves a layer 14 having a planar upper surface at a level no lower than the upper surface of the upper conductor pattern 8 outside the via-hole regions. This planarization layer 14 may, for example, comprise a conductor material such as e.g. PEDOT or graphene, or an insulator/dielectric material such as e.g. SU8 or Solvene.

The planarization layer 14 is then patterned to expose substantially the whole area of the pixel conductors outside the via-hole regions. Even after this patterning of the planarization layer 14, the resulting topographic profile of the upper surface of the workpiece W is flatter than before forming the planarization layer 14.

An alignment layer 16 (e.g. thin organic polyimide layer rubbed with a cloth in one direction) is then formed over the workpiece W to cover the whole upper surface of the workpiece W to complete the backplane, and another support component is prepared including e.g. a plastic support film 30 supporting at least another alignment layer 32 (e.g. organic polyimide layer). Liquid crystal material 34 fills a space between the backplane and the other support component created by spacer elements (not shown). The spacer elements may, for example, form an integral part of either or both of the backplane and other support component, or may comprise separate elements such as spacer balls.

The example embodiment illustrated in FIGS. 3(a) to 3(e) similarly involves forming a planarization layer 14 over the work piece. However, the next steps involve patterning the planarization layer to define via-holes 18 extending down to the pixel conductors. The thickness of the planarization layer 14 outside the via-hole regions is much smaller than the thickness of the stack through which the main via-holes 10 are formed, and the depth of this second set of via-holes 18 is smaller.

Conductor material is deposited over the patterned planarization layer by e.g. sputtering, and then patterned to form a further conductor pattern 20 defining an array of upper pixel conductors each in contact with a respective lower pixel conductor of the pixel conductor pattern 8.

Banks 22 are then formed from an insulator material in the regions between upper pixel conductors of the upper pixel conductor pattern 20 to define wells for receiving LED materials 36 including an organic light-emitting material. The area of each well includes the respective via-hole region in which the via-holes 10 are formed in the stack 4.

In these embodiments, no inorganic moisture barrier layer is formed directly on the planarization layer 14, or anywhere between the planarization layer 14 and the optical medium (not anywhere between the planarisation layer 14 and the alignment layer 16 adjacent the LC material 34 in the case of the LCD device, and not anywhere between the planarization layer 14 and the banks 22/LED materials 36 in the case of the LED device). No unpatterned inorganic insulator material (such as an inorganic nitride or oxide material) is deposited on the planarization layer 14 over the whole surface of the workpiece W by a deposition technique that produces a high packing density and thus a low transmission rate for air species such as moisture and oxygen. The planarization layer 14 is provided not for the purpose of facilitating the formation of a good moisture barrier layer, but to improve the quality of the display image.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method comprising: providing a workpiece including a stack of layers defining an array of transistors including organic semiconductor channels, wherein the stack of layers comprises an upper conductor pattern defining an array of upper conductor elements, each in contact with a respective lower conductor element of a lower conductor pattern in via-hole regions; the method comprising: processing the workpiece by forming over the upper conductor pattern a plugging layer that raises the upper surface level of the workpiece in at least the via-hole regions whilst leaving at least a portion of each upper conductor element exposed; and providing an optical medium over the upper conductor pattern without first forming an inorganic moisture barrier layer on the upper surface of the workpiece.

2. The method according to claim 1, wherein the upper surface of the plugging layer is no lower than the upper surface of the upper conductor pattern outside the via-hole regions.

3. The method according to claim 1, wherein the optical medium comprises a liquid crystal material, and the method comprises forming an alignment layer on the upper surface of the workpiece over the upper conductor pattern without first forming an inorganic moisture barrier layer over the upper surface of the workpiece.

4. The method according to claim 1, wherein the optical medium comprises a light-emitting diode comprising an organic light-emitting material, and the method comprises forming an element of the light-emitting diode over the upper surface of the workpiece without first forming an inorganic moisture barrier layer over the upper surface of the workpiece.

5. The method according to claim 1, wherein forming the plugging layer comprises forming a planarization layer over the upper surface of the work piece, and then patterning the planarization layer to expose at least a portion of each of the upper conductive elements.

6. The method according to claim 5, comprising forming a further conductor pattern over the planarization layer, the further conductor pattern defining an array of further conductive elements each in contact with a respective one of the upper conductive elements, wherein the area occupied by each further conductive element includes the via-hole region in which the respective upper conductive element contacts the respective lower conductive element.

7. A display device, comprising: a stack of layers defining an array of transistors including organic semiconductor channels, wherein the stack of layers comprises an upper conductor pattern defining an array of upper conductor elements, each in contact with a respective lower conductive element of a lower conductor pattern in a respective via-hole region; a patterned planarization layer that extends at least to the upper surface of the upper conductor pattern in the via-hole regions, and leaves at least a portion of each upper conductive element exposed; and an optical medium over the upper conductor pattern without any inorganic moisture barrier layer between the upper conductor pattern and the optical medium.

8. The display device according to claim 7, wherein the optical medium comprises a liquid crystal material, and device comprises an alignment layer over the upper conductor pattern without any inorganic moisture barrier layer between the upper conductor pattern and the alignment layer.

9. The display device according to claim 7, wherein the optical medium comprises a light-emitting diode comprising an organic light-emitting material, and the display device comprises an element of the light-emitting diode over the upper conductor pattern without any inorganic moisture barrier layer between the upper conductor pattern and the element of the light-emitting diode.

10. The display device according to claim 9, comprising a further conductor pattern over the patterned planarization layer, the further conductor pattern defining an array of further conductive elements each in contact with a respective one of the upper conductive elements; wherein the area occupied by each further conductive element includes the via-hole region in which the respective upper conductive element contacts the respective lower conductive element.

11. The method according to claim 1, wherein forming the plugging layer comprises forming a planarisation layer over the upper conductor pattern, wherein the planarisation layer has a planar upper surface at a level no lower than the upper surface of the upper conductor pattern; and patterning the planarisation layer so as to expose the upper conductor elements outside the via-hole regions; wherein, after the patterning, the upper surface of the planarisation layer in the via-hole regions is at a level lower than the upper surface of the conductor pattern outside the via-regions.

12. The method according to claim 1, further comprising: forming banks to define wells, wherein the wells occupy areas including at least the via-hole regions.

13. The method according to claim 2, further comprising: depositing light-emitting material into the wells.

14. The device according to claim 7, further comprising: banks defining wells, wherein the wells occupy areas including at least the via-hole regions.

15. The method according to claim 7, further comprising: light-emitting material in the wells.

16. A display device, comprising: a stack of layers defining an array of transistors including organic semiconductor channels, wherein the stack of layers comprises an upper conductor pattern defining an array of upper conductor elements, each in contact with a respective lower conductive element of a lower conductor pattern in a respective via-hole region; a patterned planarization layer occupying at least the whole area of the via-hole regions, wherein the patterned planarisation layer is over the lower conductor pattern in the via-hole regions, and has an upper surface at a level lower than the level of the upper surface of the upper conductor pattern outside the via-regions; and wherein the device further comprises an optical medium over the upper conductor pattern without any inorganic moisture barrier layer between the upper conductor pattern and the optical medium.

17. The device according to claim 16, wherein the level of the upper surface of the patterned planarisation layer is higher than the level of the interface outside the via-hole regions between the upper conductor pattern and an underlying layer.
